(19) United States
(12) Patent Application Publication
(10) Pub. No.: US 2024/0105550 A1
(43) Pub. Date: Mar. 28, 2024

(54) Water Cooling System for Semiconductor Package

(71) Applicant: Taiwan Semiconductor Manufacturing Co., Ltd, Hsinchu (TW)

(72) Inventors: Tung-Liang Shao, Hsinchu (TW); Yu-Sheng Huang, Hemei Township (TW); Hung-Yi Kuo, Taipei City (TW); Chen-Hua Yu, Hsinchu (TW)

(21) Appl. No.: 18/152,314

(22) Filed: Jan. 10, 2023

Related U.S. Application Data
(60) Provisional application No. 63/376,714, filed on Sep. 22, 2022.

(51) Int. Cl. H01L 23/433; H01L 23/367; H05K 7/20

(52) U.S. Cl. CPC H01L 23/433; H01L 23/3675; H05K 7/20218

(57) ABSTRACT

A device includes an integrated circuit die attached to a substrate; a lid attached to the integrated circuit die; a sealant on the lid; a spacer structure attached to the substrate adjacent the integrated circuit die; and a cooling cover attached to the spacer structure, wherein the cooling cover extends over the lid, wherein the cooling cover attached to the lid by the sealant. In an embodiment, the device includes a ring structure on the substrate, wherein the ring structure is between the spacer structure and the integrated circuit die.

### PRIORITY CLAIM AND CROSS-REFERENCE

This application claims the benefit of U.S. Provisional Application No. 63/376,714, filed on Sep. 22, 2022, entitled “Water Cooling System for Semiconductor Package,” which application is incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is package-on-package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, and 6 illustrate cross-sectional views of intermediate steps in the formation of a semiconductor device, in accordance with some embodiments.

FIGS. 7 and 8 illustrate cross-sectional views of intermediate steps in the packaging of a semiconductor device, in accordance with some embodiments.

FIG. 9 illustrates a cross-sectional view of an intermediate step in the packaging of a semiconductor device including a spacer structure, in accordance with some embodiments.

FIGS. 10 and 11 illustrate cross-sectional views of intermediate steps in the packaging of a semiconductor device, in accordance with some embodiments.

FIG. 12 illustrates a schematic view of a semiconductor device coupled to a cooling cover, in accordance with some embodiments.

FIG. 13 illustrates a cross-sectional view of an intermediate step in the packaging of a semiconductor device including a spacer structure, in accordance with some embodiments.

FIG. 14 illustrates a cross-sectional view of an intermediate step in the packaging of a semiconductor device including a conformal cooling cover, in accordance with some embodiments.

FIG. 15 illustrates a cross-sectional view of an intermediate step in the packaging of a semiconductor device including an L-shaped spacer structure, in accordance with some embodiments.

FIG. 16 illustrates a cross-sectional view of an intermediate step in the packaging of a semiconductor device including an L-shaped spacer structure and a conformal cooling cover, in accordance with some embodiments.

FIG. 17 illustrates a cross-sectional view of an intermediate step in the packaging of a semiconductor device including a spacer structure, in accordance with some embodiments.

FIG. 18 illustrates a cross-sectional view of an intermediate step in the packaging of a semiconductor device including a conformal cooling cover, in accordance with some embodiments.

FIG. 19 illustrates a cross-sectional view of an intermediate step in the packaging of a semiconductor device including an L-shaped spacer structure, in accordance with some embodiments.

FIG. 20 illustrates a cross-sectional view of an intermediate step in the packaging of a semiconductor device including an L-shaped spacer structure and a conformal cooling cover, in accordance with some embodiments.

FIG. 21 illustrates a cross-sectional view of an intermediate step in the packaging of a semiconductor device including a spacer structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a packaged semiconductor device, which includes a spacer structure that supports a cooling cover that provides liquid coolant to cool the semiconductor device. The spacer structure keeps the cooling cover separated from the semiconductor device, and thus reduces the chance of the semiconductor device being damaged by the cooling cover. The spacer structure also provides improved robustness for the packaged semiconductor device, and reduces forces imparted on the semiconductor device during packaging. Various combinations and configurations of spacer structures and cooling covers are described.

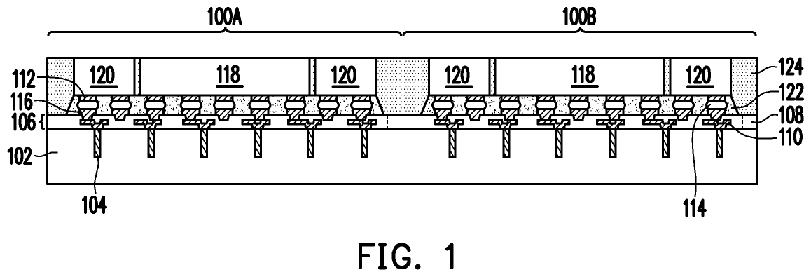

FIG. 1 illustrates a cross-sectional view of first integrated circuit dies 118 and second integrated circuit dies 120 bonded to a wafer 102, in accordance with some embodiments. FIG. 1A illustrates the wafer 102 as including two device regions 100A-100B, which may be singulated in subsequent steps to form a plurality of semiconductor devices 100. However, the wafer 102 may include any number of the device regions.

The wafer 102 may include a semiconductor substrate, such as silicon, doped or un-doped, or an active layer of a semiconductor-on-insulator (SOI) substrate. The wafer 102 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. In some embodiments, the wafer 102 may be an interposer wafer, with each of the device regions 100A-100B being subsequently singulated to form an interposer. In embodiments in which the wafer 102 is an interposer wafer, the wafer 102 may be free from active devices and may provide interconnections between the first integrated circuit dies 118 and the second integrated circuit dies 120. The interposer wafer may include optional passive devices. The wafer 102 includes a front side (e.g., the surface facing upwards in FIG. 1) a back side (e.g., the surface facing downwards in FIG. 1).

Devices may be formed at the front side (e.g. at an active surface) of the wafer 102. The devices may include optional active devices (e.g., transistors, diodes, or the like), capacitors, resistors, or the like. In some embodiments, the back side (e.g., an inactive surface) may be free from the devices. An inter-layer dielectric (ILD) may be formed over the front side of the wafer 102. The ILD may surround and cover the devices. The ILD may include one or more dielectric layers formed of materials such as phospho-silicate glass (PSG), boro-silicate glass (BSG), boron-doped phospho-silicate glass (BPSG), un-doped silicate glass (USG), or the like.

An interconnect structure 106 may be formed over the front side of the wafer 102. The interconnect structure 106 may interconnect the devices at the front side of the wafer 102 and may provide interconnections between the first integrated circuit dies 118 and the second integrated circuit dies 120 bonded to the wafer 102 in each of the device regions 100A-100B. The interconnect structure 106 may comprise one or more layers of first conductive features 110 formed in one or more stacked first dielectric layers 108. Each of the stacked first dielectric layers 108 may comprise a dielectric material, such as a low-k dielectric material, an extra low-k (ELK) dielectric material, or the like. The first dielectric layers 108 may be deposited using an appropriate process, such as, chemical vapor deposition (CVD), atomic layer deposition (ALD), physical vapor deposition (PVD), plasma-enhanced chemical vapor deposition (PECVD), or the like.

The first conductive features 110 may comprise conductive lines and conductive vias interconnecting the layers of conductive lines. The conductive vias may extend through respective ones of the first dielectric layers 108 to provide vertical connections between layers of the conductive lines. The first conductive features 110 may be formed through any acceptable process, such as, a damascene process, a dual damascene process, or the like.

In some embodiments, the first conductive features 110 may be formed using a damascene process in which a respective first dielectric layer 108 is patterned utilizing a combination of photolithography and etching techniques to form trenches corresponding to the desired pattern of the first conductive features 110. An optional diffusion barrier and/or optional adhesion layer may be deposited and the trenches may then be filled with a conductive material. Suitable materials for the barrier layer include titanium, titanium nitride, titanium oxide, tantalum, tantalum nitride, titanium oxide, combinations thereof, or the like, and suitable materials for the conductive material include copper, silver, gold, tungsten, aluminum, ruthenium, cobalt, molybdenum, combinations thereof, or the like. In some embodiments, the first conductive features may be deposited by front-end-of-line (FEOL) processes, which allows for high-temperature materials to be used for the conductive material. In an embodiment, the first conductive features 110 may be formed by depositing a seed layer of copper or a copper alloy, and filling the trenches by electroplating. A chemical-mechanical planarization (CMP) process or the like may be used to remove excess conductive material from a surface of the respective first dielectric layer 108 and to planarize surfaces of the first dielectric layer 108 and the first conductive features 110 for subsequent processing.

Although the interconnect structure 106 is illustrated in FIG. 1 as extending across a surface of the wafer 102, in some embodiments, individual interconnect structures 106 may be formed in each of the device regions 100A-100B and the individual interconnect structures 106 may be separated from one another. For example, as illustrated by dashed lines in the first dielectric layers 108 of FIG. 1, the interconnect structure 106 may be separated into individual interconnect structures 106 in each of the device regions 100A-100B. The interconnect structure 106 may be separated using a suitable etching process, such as an isotropic etching process (e.g., a wet etching process), an anisotropic etching process (e.g., a dry etching process), multiple processes or combinations thereof, or the like.

Conductive vias 104 may be formed extending into the wafer 102. The conductive vias 104 may be electrically coupled to the first conductive features 110 of the interconnect structure 106. As an example, the conductive vias 104 may be formed by forming recesses in the wafer 102 by, for example, etching, milling, laser techniques, a combination thereof, or the like. A thin dielectric material may be formed in the recesses, such as by using an oxidation technique. A barrier layer may be conformally deposited in the openings, such as by CVD, ALD, PVD, thermal oxidation, a combination thereof, or the like. The barrier layer may be formed from an oxide, a nitride, or an oxynitride, such as titanium nitride, titanium oxynitride, tantalum nitride, tantalum oxynitride, tungsten nitride, a combination thereof, and/or the like. A conductive material may be deposited over the barrier layer and in the openings. The conductive material may be formed by an electro-chemical plating process, CVD, PVD, a combination thereof, or the like. Examples of conductive materials are copper, tungsten, aluminum, silver, gold, a combination thereof, or the like. Excess of the conductive material and the barrier layer is removed from the surface of the wafer 102 by, for example, a CMP or the like. Remaining portions of the barrier layer and the conductive material form the conductive vias 104.

In the embodiment illustrated, the conductive vias 104 are not yet exposed at the back side of the wafer 102. Rather, the conductive vias 104 are buried in the wafer 102. As will be discussed in greater detail below, the conductive vias 104 will be exposed at the back side of the wafer 102 in subsequent processing. After exposure, the conductive vias 104 can be referred to as through-silicon vias or through-substrate vias (TSVs).

Further in FIG. 1, bond pads 112 are formed for external connection to the interconnect structure 106. The bond pads 112 include bump portions on and extending along a major surface of a topmost layer of the first dielectric layers 108. The bond pads 112 further include via portions extending through the topmost layer of the first dielectric layers 108. The via portions may physically contact and be electrically coupled to the first conductive features 110. As a result, the bond pads 112 may be electrically coupled to the devices formed in the wafer 102 and the conductive vias 104. The bond pads 112 may be formed of the same materials and by the same processes as the first conductive features 110.

Conductive connectors 114 are formed over the bond pads 112. The conductive connectors 114 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 114 may include a conductive material such as solder, copper, aluminum, gold, nickel, silver, palladium, tin, the like, or a combination thereof. In some embodiments, the conductive connectors 114 are formed by initially forming a layer of solder through evaporation, electroplating, printing, solder transfer, ball placement, or the like. Once the layer of solder has been formed, a reflow may be performed in order to shape the material into the desired bump shapes. In some embodiments, the conductive connectors 114 comprise metal pillars (such as copper pillars), which may be formed by sputtering, printing, electroplating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The first integrated circuit dies 118 and the second integrated circuit dies 120 are coupled to the wafer 102. Any number of the first integrated circuit dies 118 and the second integrated circuit dies 120 may be formed in each of the device regions 100A-100B. Although the first integrated circuit dies 118 and the second integrated circuit dies 120 are illustrated as having the same heights, the first integrated circuit dies 118 and the second integrated circuit dies 120 may have various heights.

Each of the first integrated circuit dies 118 and the second integrated circuit dies 120 may include bond pads 116, which are formed on a front side (e.g., an active surface) thereof. The bond pads 116 may be the same as or similar to the bond pads 112. The first integrated circuit dies 118 and the second integrated circuit dies 120 may be mechanically and electrically bonded to the wafer 102 by way of the bond pads 116, the conductive connectors 114, and the bond pads 112. The first integrated circuit dies 118 and the second integrated circuit dies 120 may be placed over the wafer 102 and a reflow process may be performed to reflow the conductive connectors 114 and bond the bond pads 112 to the bond pads 116 through the conductive connectors 114.

Each of the first integrated circuit dies 118 and the second integrated circuit dies 120 may be a logic die (e.g., a central processing unit (CPU), a graphics processing unit (GPU), a system-on-a-chip (SoC), an application processor (AP), a microcontroller, or the like), a memory die (e.g., a dynamic random access memory (DRAM) die, a static random access memory (SRAM) die, a high bandwidth memory (HBM) die, or the like), a power management die (e.g., a power management integrated circuit (PMIC) die), a radio frequency (RF) die, a sensor die, a micro-electro-mechanical-system (MEMS) die, a signal processing die (e.g., a digital signal processing (DSP) die or the like), a front-end die (e.g., an analog front-end (AFE) die), the like, or a combination thereof. In some embodiments, the first integrated circuit dies 118 may be SoCs and the second integrated circuit dies 120 may be HBM dies.

Still referring to FIG. 1, an underfill 122 may be formed between the first integrated circuit dies 118 and the second integrated circuit dies 120 and the interconnect structure 106, surrounding the bond pads 112, the bond pads 116, and the conductive connectors 114. The underfill 122 may reduce stress and protect the joints resulting from the reflowing of the conductive connectors 114. The underfill 122 may be formed by a capillary flow process after the first integrated circuit dies 118 and the second integrated circuit dies 120 are attached, or may be formed by a suitable deposition method before the first integrated circuit dies 118 and the second integrated circuit dies 120 are attached.

In some embodiments, an encapsulant 124 is formed on and around the various components. After formation, the encapsulant 124 encapsulates the first integrated circuit dies 118, the second integrated circuit dies 120, and the underfill 122. In embodiments in which individual interconnect structures 106 are included in each of the device regions 100A-100B, the encapsulant may further encapsulate the interconnect structures 106. The encapsulant 124 may be a molding compound, epoxy, or the like. The encapsulant 124 may be applied by compression molding, transfer molding, or the like, and may be formed over the wafer 102 such that the first integrated circuit dies 118 and/or the second integrated circuit dies 120 are buried or covered. The encapsulant 124 may further be formed in gap regions between the first integrated circuit dies 118 and/or the second integrated circuit dies 120. The encapsulant 124 may be applied in liquid or semi-liquid form and then subsequently cured.

A planarization process may be performed on the encapsulant 124 to expose the first integrated circuit dies 118 and the second integrated circuit dies 120, in some embodiments. The planarization process may also remove material of the first integrated circuit dies 118 and/or the second integrated circuit dies 120 until the first integrated circuit dies 118 and the second integrated circuit dies 120 are exposed. Top surfaces of the first integrated circuit dies 118, the second integrated circuit dies 120, and the encapsulant 124 may be substantially coplanar (e.g., level) after the planarization process, within process variations. The planarization process may be, for example, a chemical-mechanical polish (CMP), a grinding process, or the like. In some embodiments, the planarization may be omitted, for example, if the first integrated circuit dies 118 and/or the second integrated circuit dies 120 are already exposed.

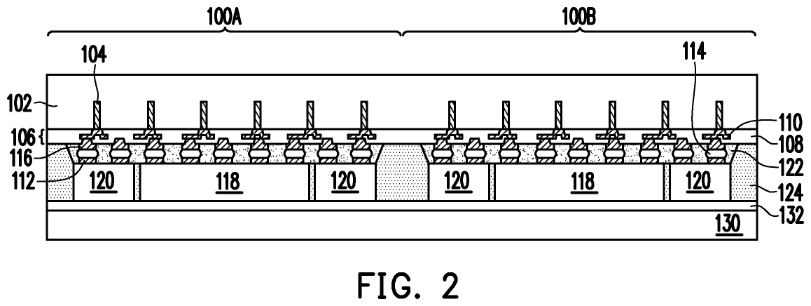

In FIG. 2, a carrier substrate 130 is bonded to the encapsulant 124, the first integrated circuit dies 118, and the second integrated circuit dies 120, in accordance with some embodiments. The carrier substrate 130 may be bonded, for example, using a release layer 132 or the like. The carrier substrate 130 may be a glass carrier substrate, a ceramic carrier substrate, or the like. The carrier substrate 130 may be a wafer or panel, such that multiple packages can be formed on the carrier substrate 130 simultaneously.

The release layer 132 may be formed of a polymer-based material, which may be removed along with the carrier substrate 130 from the overlying structures that will be formed in subsequent steps. In some embodiments, the release layer 132 is an epoxy-based thermal-release material, which loses its adhesive property when heated, such as a light-to-heat-conversion (LTHC) release coating. In other embodiments, the release layer 132 may be an ultra-violet (UV) glue, which loses its adhesive property when exposed to UV lights. The release layer 132 may be dispensed as a liquid and cured, may be a laminate film laminated onto the carrier substrate 130, or may be the like. The top surface of the release layer 132 may be leveled and may have a high degree of planarity. Further in FIG. 2, after the carrier substrate 130 is bonded to the encapsulant 124, the first integrated circuit dies 118, and the second integrated circuit dies 120, the structure may be flipped such that a back side of the wafer 102 faces upwards.

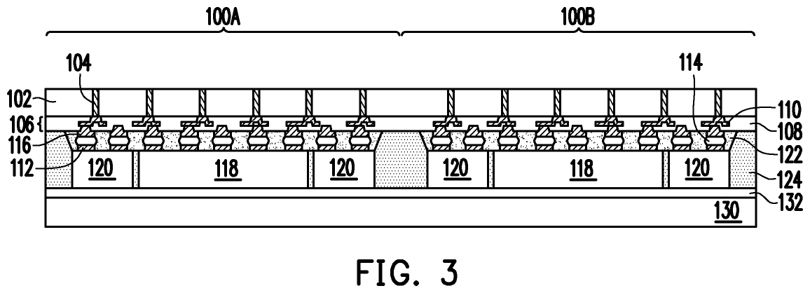

In FIG. 3, the wafer 102 is thinned, in accordance with some embodiments. The thinning may be accomplished using a CMP process, a grinding process, an etch-back process, a combination thereof, or the like. The thinning is performed on the back side surface of the wafer 102, and may expose the conductive vias 104. After the thinning, surfaces of the conductive vias 104 and the back side surface of the wafer 102 may be coplanar (e.g., level) within process variations. The exposed conductive vias 104 may be referred to as “through substrate vias” or “through silicon vias” (TSVs). After the wafer 102 is thinned, the conductive vias 104 may provide electrical connections through the substrate of the wafer 102.

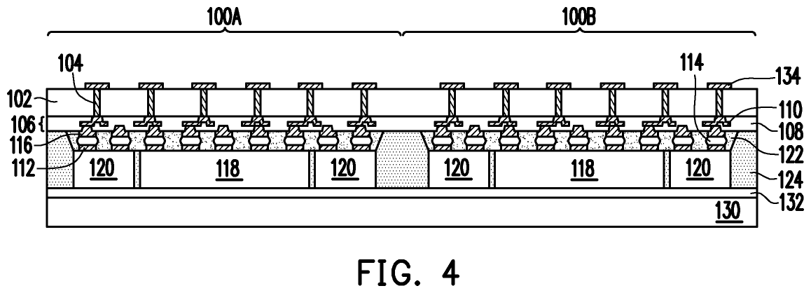

In FIG. 4, die connectors 134 are formed at the back side of the wafer 102, in accordance with some embodiments. The die connectors 134 may be physically and electrically connected to the conductive vias 104. The die connectors 134 may be conductive pillars, conductive pads, or the like, to which external connections are made. The die connectors 134 can be formed of a metal, such as copper, aluminum, or the like, and can be formed by, for example, plating, or the like. The die connectors 134 are electrically connected to devices formed in the wafer 102 and the interconnect structure 106.

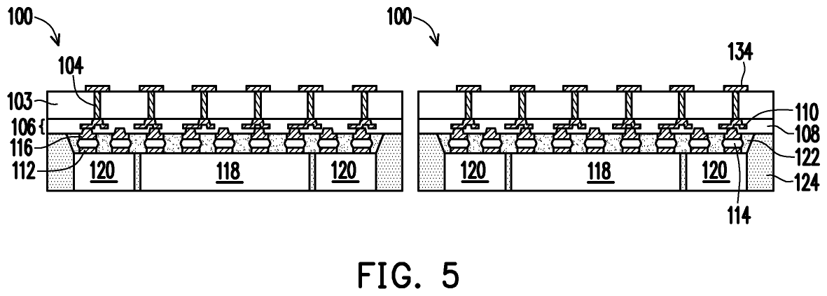

In FIG. 5, a singulation process is performed to separate individual semiconductor devices 100, in accordance with some embodiments. The singulation process may be performed by sawing along scribe line regions, for example, between the device regions 100A-100B (see FIG. 4). The sawing singulates individual semiconductor devices 100 from one another. The resulting singulated semiconductor devices 100 may be from any of the device regions 100A-100B. The singulation process singulates the wafer 102 to form substrates 103. The singulation process may also saw through the encapsulant 124 and the interconnect structure 106.

Further in FIG. 5, a carrier substrate de-bonding is performed to detach (or “de-bond”) the carrier substrate 130 from the encapsulant 124, the first integrated circuit dies 118, and the second integrated circuit dies 120. In some embodiments, the de-bonding includes projecting a light, such as a laser light or an UV light, on the release layer 132 so that the release layer 132 decomposes under the heat of the light and the carrier substrate 130 can be removed. The carrier substrate de-bonding may be performed before or after the singulation process is performed.

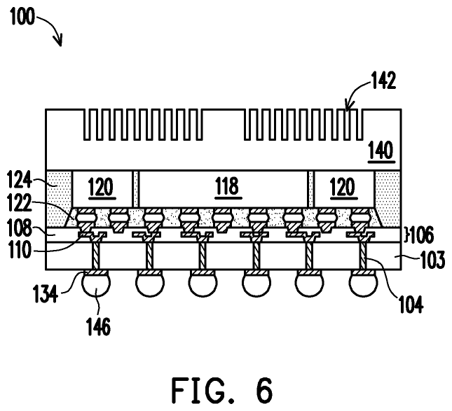

In FIG. 6, a lid 140 is attached to a semiconductor device 100, in accordance with some embodiments. In other embodiments, the lid 140 may be attached before performing the singulation process (see FIG. 5), which may saw through the lid 140. As illustrated in FIG. 6, the lid 140 may be attached to the encapsulant 124 and back sides of the first integrated circuit dies 118 and the second integrated circuit dies 120. In some embodiments, the lid 140 may comprise materials such as silicon, glass, a metal, a polymer, or the like. The lid 140 may have a thickness ranging from about 10 μm to about 10,000 μm. The semiconductor device 100 may be bonded to the lid 140 by fusion bonding or the like. In some embodiments, the semiconductor device 100 may be bonded to the lid 140 through dielectric-to-dielectric bonding, without using any adhesive material (e.g., die attach film). The bonding may include a pre-bonding and an annealing. During the pre-bonding, a small pressing force is applied to press the semiconductor device 100 against the lid 140. The pre-bonding is performed at a low temperature, such as room temperature (e.g., a temperature in the range of about 15° C. to about 30° C.). In some embodiments, an oxide, such as a native oxide, is formed at the back side of the lid 140 and is used for the bonding. The bonding strength is then improved in a subsequent annealing step, in which the semiconductor device 100 and the lid 140 are annealed at a high temperature, such as a temperature in the range of about 100° C. to about 400° C. After the annealing, bonds, such as fusion bonds, are formed that bond the semiconductor device 100 to the lid 140. For example, the bonds can be covalent bonds between the semiconductor device 100 and the lid 140. Bonding the lid 140 directly to the first integrated circuit dies 118 and the second integrated circuit dies 120 through fusion bonding may decrease thermal resistance between the lid and the first integrated circuit dies 118 and the second integrated circuit dies 120, which may improve the cooling capacity of the lid 140.

In some embodiments, the lid 140 may be attached to the semiconductor device 100 using an adhesive. The lid 140 may be attached to the semiconductor device 100 using the adhesive in combination with the dielectric-to-dielectric bonding, or in lieu of the dielectric-to-dielectric bonding. The adhesive may be a thermal interface material (TIM) or other adhesive. The TIM may be an adhesive material having good thermal conductivity. The adhesive may be any suitable adhesive, epoxy, die attach film (DAF), or the like. The adhesive may be deposited between the lid 140 and any of the encapsulant 124, the first integrated circuit dies 118, and/or the second integrated circuit dies 120.

In some embodiments, the lid 140 may be coupled to the semiconductor device 100 using glass frit bonding. The lid 140 may be coupled to the semiconductor device 100 using glass frit bonding in combination with the dielectric-to-dielectric bonding, or in lieu of the dielectric-to-dielectric bonding. The glass frit bonding may include depositing a glass material, such as a glass paste, a glass solder or the like, between the lid 140 and the semiconductor device 100 and heating the glass material to reflow the glass material. The glass material may be deposited between the lid 140 and any of the encapsulant 124, the first integrated circuit dies 118, and/or the second integrated circuit dies 120.

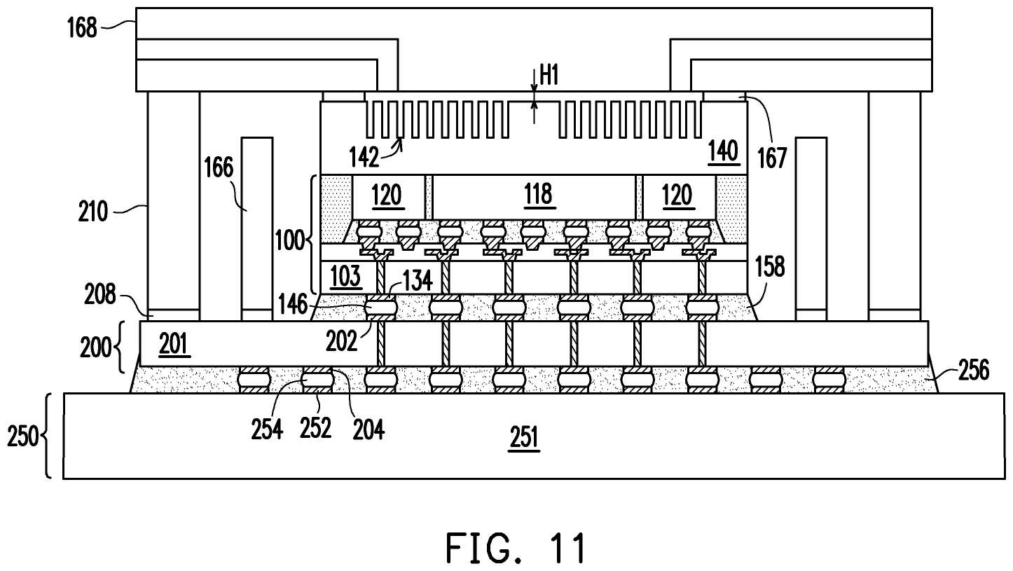

As illustrated in FIG. 6, the lid 140 may include channels 142 formed in the surface of the lid 140 that is opposite the semiconductor device 100. The channels 142 may be parallel or have any suitable arrangement or configuration. The channels 142 may be used to provide cooling to the semiconductor device 100. As will be discussed below, a cooling cover (such as the cooling cover 168, discussed below with respect to FIG. 11) may subsequently be attached to the lid 140 and may supply a coolant, such as a liquid coolant, to the channels 142. The presence of the channels 142 can improve the cooling capability of the lid 140, which can allow for materials such as silicon or the like to be used for the lid 140 instead of costlier materials such as copper. Materials of the lid 140 may be compatible with semiconductor processing apparatuses and may easily be integrated into the semiconductor device manufacturing process.

Further in FIG. 6, conductive connectors 146 may be formed on the die connectors 134, in accordance with some embodiments. The conductive connectors 146 may be ball grid array (BGA) connectors, solder balls, metal pillars, controlled collapse chip connection (C4) bumps, micro bumps, electroless nickel-electroless palladium-immersion gold technique (ENEPIG)-formed bumps, or the like. The conductive connectors 146 may include a conductive material such as solder, copper, aluminum, gold, nickel, silver, palladium, tin, the like, or a combination thereof. In some embodiments, the conductive connectors 146 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 146 comprise metal pillars (such as copper pillars) formed by sputtering, printing, electroplating, electroless plating, CVD, or the like. In embodiments in which the conductive connectors comprise metal pillars, the metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

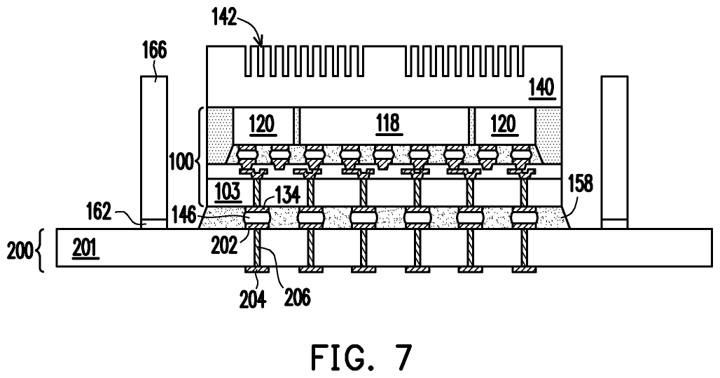

In FIG. 7, a device substrate 200 is connected to the semiconductor device 100, in accordance with some embodiments. The device substrate 200 may provide additional interconnection and physical support for the semiconductor device 100. In some embodiments, the device substrate 200 may be an interposer. The device substrate 200 may include a substrate 201, which may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate 201 may be a silicon-on-insulator (SOI) substrate. Generally, an SOI substrate includes a layer of a semiconductor material such as epitaxial silicon, germanium, silicon germanium, SOI, silicon germanium on insulator (SGOI), or combinations thereof. In some embodiments, the substrate 201 may be based on an insulating core such as a fiberglass reinforced resin core. In some embodiments, the core material may be a fiberglass resin such as FR4. In some embodiments, the core material may include bismaleimide-triazine (BT) resin, other printed circuit board (PCB) materials, or other films. Build up films such as Ajinomoto build-up film (ABF) or other laminates may be used for the substrate 201. Other materials are possible. In some embodiments, the device substrate 200 may have a thickness in the range of about 800 μm to 1500 μm, though other thicknesses are possible.

The device substrate 200 may include active and passive devices (not separately illustrated). A wide variety of devices such as transistors, capacitors, resistors, combinations of these, and the like may be included. The devices may be formed using any suitable methods. The device substrate 200 may also include metallization layers (not shown) and/or conductive vias 206, in some embodiments. The metallization layers may be formed over the active and passive devices and are designed to connect the various devices to form functional circuitry. The metallization layers may be formed of alternating layers of dielectric materials (e.g., low-k dielectric materials) and conductive materials (e.g., copper) with vias interconnecting the layers of conductive materials. The metallization layers may be formed through any suitable processes (such as deposition, damascene, dual damascene, or the like). In some embodiments, the device substrate 200 is free or substantially free of active and passive devices.

The device substrate 200 may include bond pads 202 formed on a first side of the substrate 201 and bond pads 204 on a second side of the substrate 201 opposite the first side of the substrate 201. The bond pads 202 may be coupled to the conductive connectors 146. In some embodiments, the bond pads 202 and the bond pads 204 may be formed by forming recesses (not separately illustrated) into dielectric layers (not separately illustrated) on the first and second sides of the substrate 201. The recesses may be formed to allow the bond pads 202 and the bond pads 204 to be embedded into the dielectric layers. In some embodiments, the recesses are omitted and the bond pads 202 and the bond pads 204 may be formed on the dielectric layers. In some embodiments, the bond pads 202 and the bond pads 204 include a thin seed layer (not separately illustrated) made of copper, titanium, nickel, gold, palladium, the like, or a combination thereof. The conductive materials of the bond pads 204 and the bond pads 204 may be deposited over the thin seed layer. The conductive materials may be formed by an electro-chemical plating process, an electroless plating process, CVD, atomic layer deposition (ALD), PVD, the like, or a combination thereof. In an embodiment, the conductive materials of the bond pads 202 and the bond pads 204 include copper, tungsten, aluminum, silver, gold, the like, or a combination thereof. Other materials are possible.

In some embodiments, the bond pads 202 and the bond pads 204 are UBMs that include three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the bond pads 202 and the bond pads 204. Any suitable materials or layers of materials that may be used for the bond pads 202 and the bond pads 204 are fully intended to be included within the scope of the current application. In some embodiments, the conductive vias 206 extend through the substrate 201 and couple at least one of the bond pads 202 to at least one of the bond pads 204.

The device substrate 200 may be mechanically and electrically bonded to the semiconductor device 100 by the bond pads 202, the conductive connectors 146, and the die connectors 134. The device substrate 200 may be placed over the semiconductor device 100 and a reflow process may be performed to reflow the conductive connectors 146 and bond the bond pads 202 to the die connectors 134 through the conductive connectors 146.

An underfill 158 may then be formed between the semiconductor device 100 and the device substrate 200, in some embodiments. The underfill 158 may surround the bond pads 202, the die connectors 134, and the conductive connectors 146. The underfill 158 may reduce stress and protect the joints resulting from the reflowing of the conductive connectors 146. The underfill 158 may be formed by a capillary flow process after the device substrate 200 is attached to the semiconductor device 100, or may be formed by a suitable deposition method before the device substrate 200 is attached.

Further in FIG. 7, a ring structure 166 may be attached to the device substrate 200, in accordance with some embodiments. The ring structure 166 may be attached to protect the semiconductor device 100, to add stability to the device substrate 200, and/or to dissipate heat from the semiconductor device 100 and the device substrate 200. The ring structure 166 may be formed from a material having a high thermal conductivity, such as steel, stainless steel, copper, aluminum, combinations thereof, or the like. In some embodiments, the ring structure 166 may be a metal coated with another metal, such as gold. Other materials are possible.

An adhesive 162 may be used to attach the ring structure 166 to the substrate 201, in some embodiments. The adhesive may be any suitable adhesive, epoxy, die attach film (DAF), or the like. In some embodiments, the adhesive 162 may be a thermal interface material (TIM), such as an adhesive material having a good thermal conductivity. The ring structure 166 may encircle the semiconductor device 100. In some embodiments, a top surface of the ring structure 166 is lower than a top surface of the lid 140, as shown in FIG. 7. In other embodiments, a top surface of the ring structure 166 may be approximately level with a top surface of the lid 140, or a top surface of the ring structure 166 may be higher than a top surface of the lid 140.

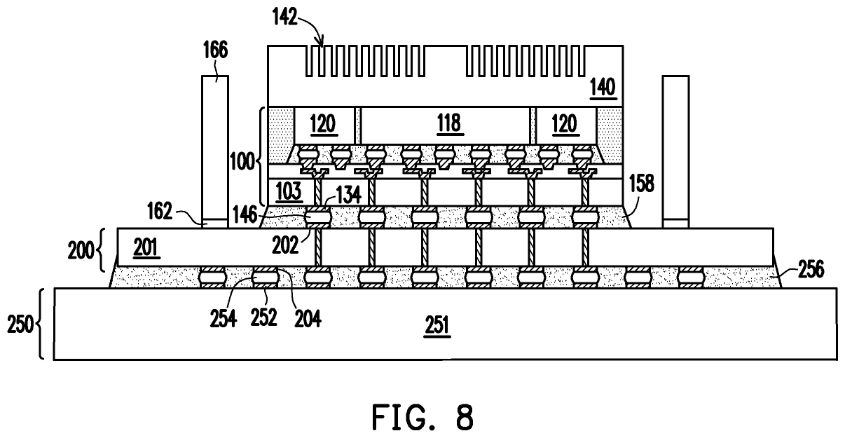

In FIG. 8, a package substrate 250 is connected to the device substrate 200, in accordance with some embodiments. The package substrate 250 may provide additional interconnection and physical support for the device substrate 200, and may be part of a larger device or package. For example, in some embodiments, the package substrate 250 may be a PCB mainboard, an interconnect structure, an interposer, or other type of structure. The package substrate 250 may include a substrate 251, which may be a semiconductor material or SOI substrate such as those described previously for the substrate 201. In some embodiments, the substrate 251 may be based on an insulating core such as a fiberglass reinforced resin core. In some embodiments, the core material may be a fiberglass resin such as FR4. In some embodiments, the core material may include BT resin, other PCB materials, or other films. Build up films such as ABF or other laminates may be used for the substrate 251. Other materials are possible.

The package substrate 250 may include active devices, passive devices metallization layers, and/or conductive vias, in some embodiments. In some embodiments, the package substrate 250 is free or substantially free of active and passive devices. The package substrate 250 may include bond pads 252 formed on the substrate 251, in some embodiments. The bond pads 252 may be similar to the bond pads 250 described for FIG. 7, and may be formed using similar techniques. In some embodiments, the bond pads 252 are UBMs. The bond pads 252 may be connected to the bond pads 204 of the device substrate 200 by conductive connectors 254. The conductive connectors 254 may be similar to the conductive connectors 146 described previously for FIG. 6, and may be formed using similar techniques. The package substrate 250 may be mechanically and electrically bonded to the device substrate 200 by the bond pads 252, the conductive connectors 254, and the bond pads 204. The device substrate 200 may be placed over the package substrate 250 and a reflow process may be performed to reflow the conductive connectors 254 and bond the bond pads 252 to the bond pads 204 through the conductive connectors 254. An underfill 256 may then be formed between the device substrate 200 and the package substrate 250, in some embodiments. The underfill 256 may surround the bond pads 252, the conductive connectors 254, and the bond pads 204. The underfill 256 may be similar to the underfill 158 described previously for FIG. 7, and may be formed using similar techniques.

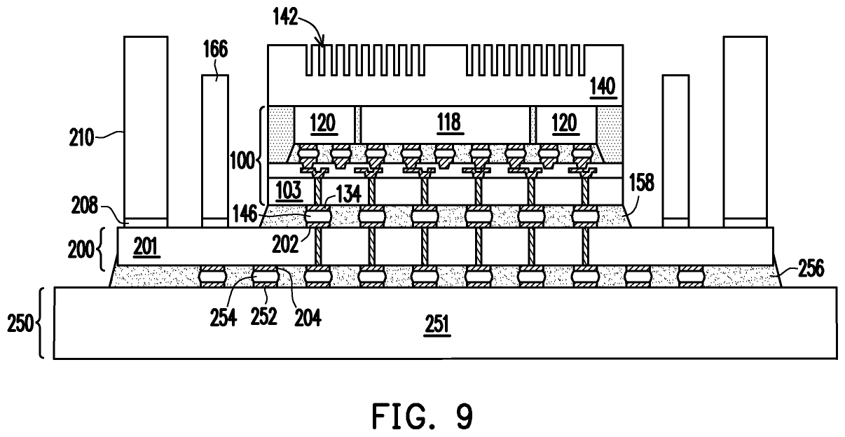

In FIG. 9, a spacer structure 210 is attached to the device substrate 200, in accordance with some embodiments. The spacer structure 210 may be attached to protect the semiconductor device 100 or lid 140. For example, in some embodiments, the cooling cover 168 (see FIG. 11) may be placed on the spacer structure 210 such that the spacer structure 210 is between the substrate 201 and the cooling cover 168. The height of a top surface of the spacer structure 210 may be controlled to ensure that a gap is present between a bottom surface of the cooling cover 168 and a top surface of the lid 140. In this manner, the spacer structure 210 can prevent the cooling cover 168 from contacting the lid 140 and thus can prevent damage to the semiconductor device 100 or the lid 140 from the cooling cover 168. For example, in some embodiments, a top surface of the spacer structure 210 is higher (e.g. farther above the substrate 201) than a top surface of the lid 140. In this manner, the height of the spacer structure 210 may be used to control the height of the gap (e.g., distance H1 in FIG. 11) between a bottom surface of the cooling cover 168 and a top surface of the lid 140. The height of a top surface of the spacer structure 210 may be controlled by controlling the vertical thickness of the spacer structure 210. In some embodiments, the spacer structure 210 has a vertical thickness in the range of about 500 μm to about 5 mm, though other vertical thicknesses are possible. In some embodiments, a section of the spacer structure 210 has a width in the range of about 500 μm to about 10 mm, though other widths are possible. In other embodiments, the height of spacer structure 210 is about the same as a height of the lid 140.

The spacer structure 210 may encircle the semiconductor device 100 and the ring structure 166, in some embodiments. Outer sidewalls of the spacer structure 210 may be approximately coterminous or coplanar with sidewalls of the device substrate 200, or outer sidewalls of the spacer structure 210 may be offset from sidewalls of the device substrate 200, as shown in FIG. 9. The spacer structure 210 may comprise a single continuous piece, such as a single ring-shaped piece, or may comprise multiple pieces arranged in a ring-like shape. The spacer structure 210 may be formed from a rigid material, in some embodiments. For example, the ring structure 166 may be formed of a semiconductor material such as silicon (e.g., bulk silicon) or the like; an oxide such as silicon oxide or the like; a plastic or polymer material or the like; a metal such as steel, aluminum, or the like; a ceramic material or the like; a core-based or resin-based material or the like; combinations thereof; or the like. Other materials or combinations of materials are possible. The use of a rigid material can provide increased protection for the semiconductor device 100 or the lid 140, and can provide additional robustness to the overall structure.

An adhesive 208 may be used to attach the spacer structure 210 to the substrate 201 of the device substrate 200, in some embodiments. The adhesive 208 may be any suitable adhesive, polymer, epoxy, DAF, or the like. In some embodiments, the adhesive 208 may be a TIM such as an adhesive material having a good thermal conductivity. In some embodiments, the adhesive 208 is a silicone elastomer. Other materials are possible. The adhesive 208 may be similar to the adhesive 162 described for FIG. 7, in some cases. In some embodiments, the adhesive 208 is deposited on the substrate 201 and then the spacer structure 210 is placed on the adhesive 208. In other embodiments, the adhesive 208 is deposited on bottom surfaces of the spacer structure 210, and then the adhesive-coated surfaces of the spacer structure 210 are brought into contact with the substrate 201. In some embodiments, the adhesive 208 may be cured after attaching the spacer structure 210.

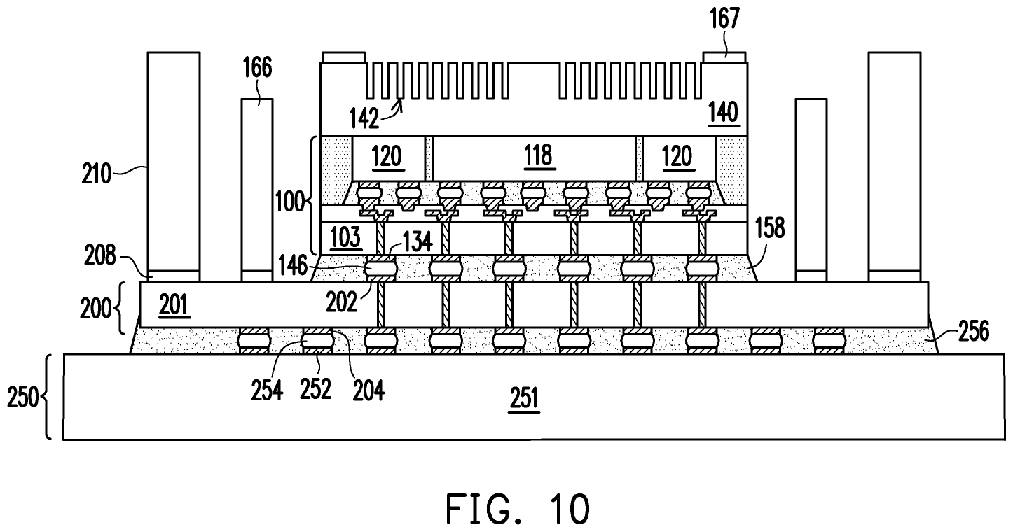

In FIG. 10, a sealant 167 is deposited on the lid 140, in accordance with some embodiments. The sealant 167 may be deposited to seal the space between the lid 140 and the cooling cover 168 to prevent coolant leakage. The sealant 167 may also act as a physical buffer that prevents the cooling cover 168 from contacting and potentially damaging the lid 140. The sealant 167 may also be adhesive to provide a more secure attachment of the cooling cover 168 to the lid 140, in some embodiments. The sealant 167 may be any suitable adhesive, polymer, polyimide, epoxy, DAF, TIM, or the like. The sealant 167 may be a soft or flexible material, in some embodiments. The sealant 167 may be deposited around the perimeter of the lid 140, and may also be deposited on surfaces of the lid 140 that are within the perimeter of the lid 140, in some embodiments.

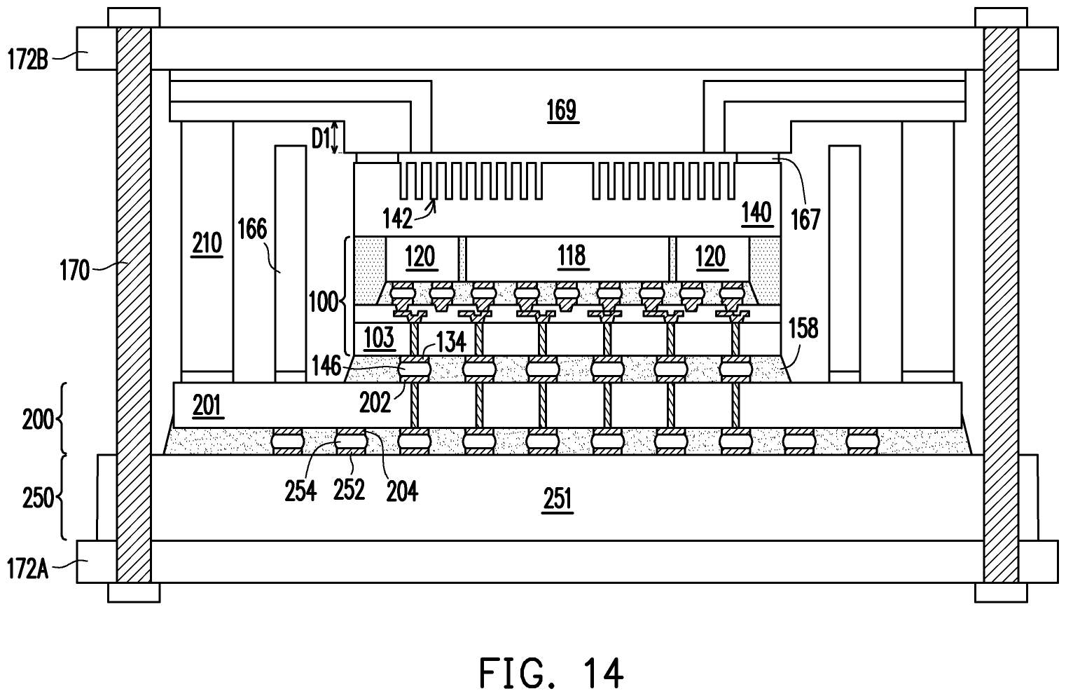

In FIG. 11, a cooling cover 168 is attached to the lid 140, in accordance with some embodiments. In some embodiments, the cooling cover 168 is placed on the spacer structure 210 and the sealant 167. The sealant 167 extends from top surfaces of the lid 140 to bottom surfaces of the cooling cover 168, and the sealant 167 may adhere the cooling cover 168 to the lid 140, in some embodiments. In other embodiments, an adhesive (not illustrated) may also be deposited on top surfaces of the spacer structure 210 to facilitate attachment of the cooling cover 168. As shown in FIG. 11, the presence of the spacer structure 210 keeps the cooling cover 168 separated from the lid 140, forming a gap between the cooling cover 168 and the lid 140. In some embodiments, the spacer structure 210 keeps a bottom surface of the cooling cover 168 separated from a top surface of the lid 140 by a distance H1 that is in the range of about 10 μm to about 2 mm, though other distances are possible. In some cases the distance H1 also corresponds to a difference in heights between a top surface of the lid 140 and a top surface of the spacer structure 210. The width of the cooling cover 168 may be approximately the same as the overall width of the spacer structure 210, or the width of the cooling cover 168 may be greater than the overall width of the spacer structure 210, as shown in FIG. 11. The cooling cover 168 may have a substantially level bottom surface, as shown in FIG. 11, but may have a bottom surface with protruding portions in other embodiments, such as the embodiment described below for FIG. 14.

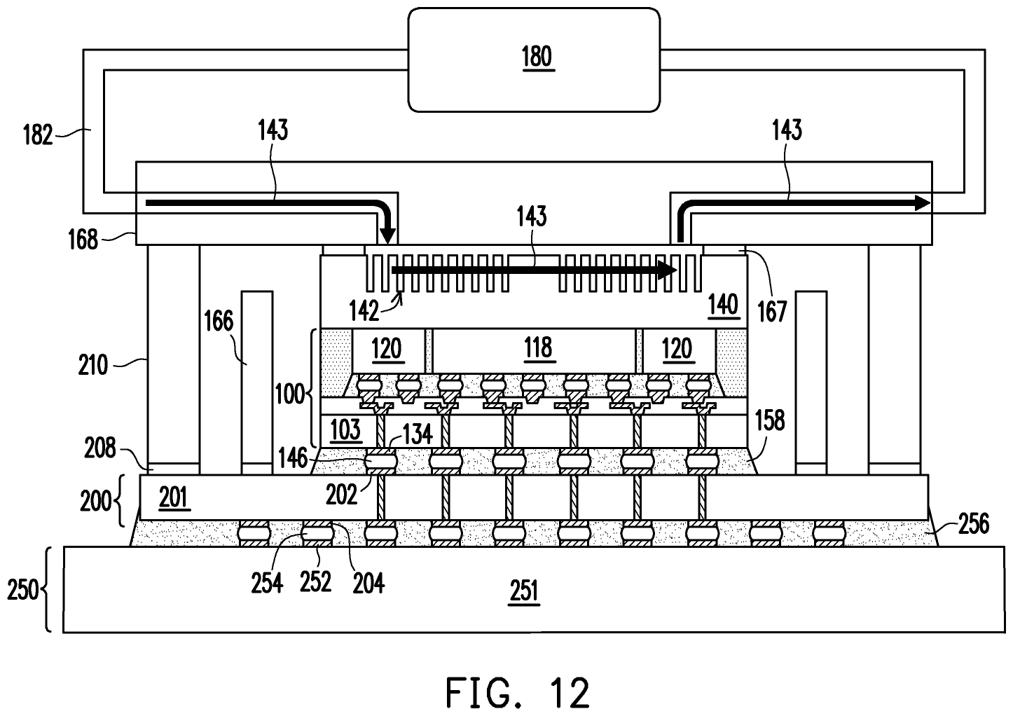

FIG. 12 illustrates the cooling cover 168 coupled to a heat transfer unit 180, in accordance with some embodiments. The illustration of FIG. 12 is a simplified schematic for explanatory and clarity purposes. In some embodiments, the cooling cover 168 may be configured to provide a coolant, such as a liquid coolant, to the channels 142 of the lid 140. As such, the cooling cover 168 may be in fluid communication with the channels 142 of the lid 140. In some embodiments, the coolant may comprise water, a dielectric coolant, a propylene glycol-based coolant, a phase change material, another conventional coolant, or the like. The coolant may flow through the channels 142 and through the gap between the lid 140 and the cooling cover 168, as indicated by the arrows 143 in FIG. 12. In embodiments in which the channels 142 are parallel to one another, the coolant may flow through the channels 142 in a direction perpendicular to longitudinal axes of the channels 142. In some embodiments, the coolant may flow through the channels 142 in a direction parallel to longitudinal axes of the channels 142.

The coolant may be provided to the cooling cover 168 by a heat transfer unit 180, which may include a chiller, a pump, a combination thereof, or the like. The heat transfer unit 180 may be connected to the cooling cover 168 by a pipe fitting 182, which may be connected to the cooling cover 168 through glue or another adhesive, a screw-type fitting, a quick connection, or the like. A single heat transfer unit 180 may be attached to one or more cooling covers 168. The heat transfer unit 180 may supply the coolant to the cooling cover 168 at a flow rate ranging from about 0.01 liters per minute to about 1,000 liters per minute. In some embodiments, the heat transfer unit 180 may comprise a pump which pumps facility water to the cooling cover 168. In some embodiments, the heat transfer unit 180 and the cooling cover 168 may only supply coolant to the channels 142 during operation. The coolant may partially or substantially fill the channels 142 of the lid 140 during operation, and the coolant may also partially or substantially fill the gap above the channels 142 during operation, in some cases.

Providing the channels 142 and flowing a coolant through the channels 142 improves the cooling capability of the lid 140. This may allow for materials such as silicon and the like to replace materials such as copper in the lid 140, which reduces costs. The channels 142 may be formed by low-cost methods, such as wet etching, die sawing, laser cutting, or the like. Materials of the lid 140 may be compatible with semiconductor processing apparatuses and may easily be integrated into semiconductor device manufacturing processes.

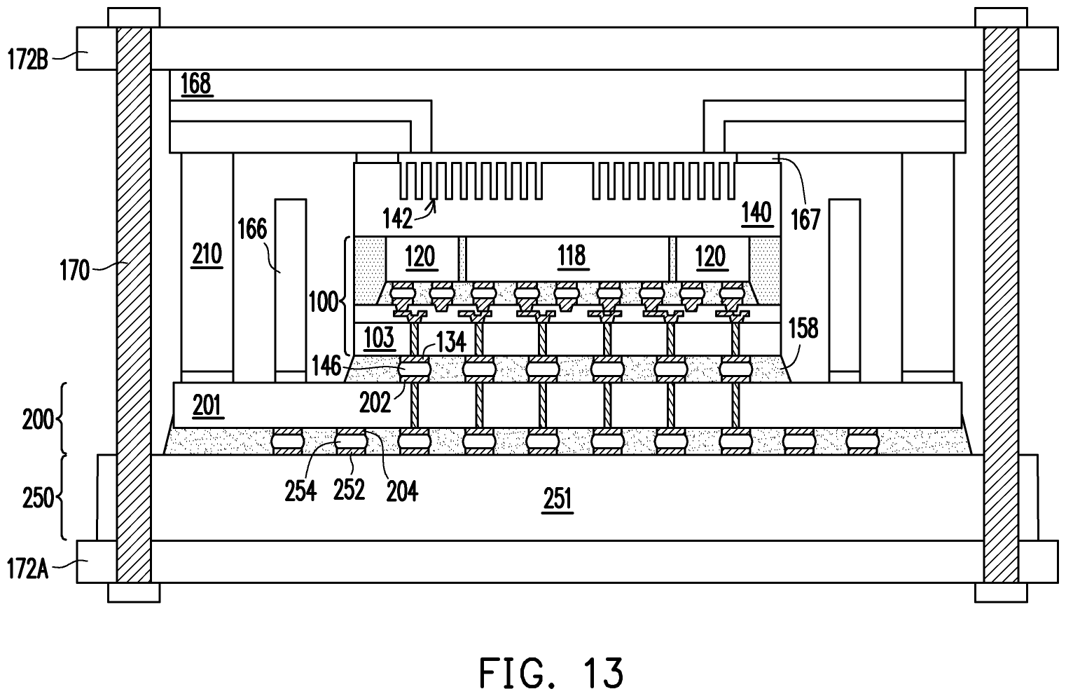

In FIG. 13, the cooling cover 168 is secured to the package substrate 250 using a frame 172 and screw-type fasteners 170, in accordance with some embodiments. The frame 172 includes a lower frame 172A on the bottom side of the package substrate 250 and an upper frame 172B on the top side of the cooling cover 168. The screw-type fasteners 70 may comprise bolts, which extend through bolt holes in the lower frame 172A and the upper frame 172B. In some embodiments, the bolts may also extend through bolt holes in the substrate 251, as shown in FIG. 13. In other embodiments, the bolts may extend through bolt holes in the substrate 201 and/or through bolt holes in the cooling cover 168. The screw-type fasteners 170 may further include fasteners that are threaded onto the bolts and tightened to clamp the lower frame 172A and the upper frame 172B together. In some embodiments, the fasteners may be nuts or the like that are threaded onto the bolts.

When the screw-type fasteners 170 are tightened, the upper frame 172B presses the cooling cover 168 against the spacer structure 210 and the sealant 167. The presence of the spacer structure 210 prevents the cooling cover 168 from being pressed into the lid 140. Additionally, the spacer structure 210 distributes the pressing force to the device substrate 200 and the package substrate 250, which results in less of the pressing force being applied to the semiconductor device 100 or the lid 140. In this manner, the use of a spacer structure 210 as described herein can allow for less warping, stress, or strain of the semiconductor device 100 or the lid 140, and thus can reduce the risk of damage, cracking, or device failure.

In other embodiments, the frame 172 is not used, and the screw-type fasteners 170 extend through and are tightened directly against the cooling cover 168, the device substrate 200, and/or the package substrate 250. Other techniques for securing the cooling cover 168 are possible, such as clamping fasteners, encapsulation, or other techniques.

FIG. 14 illustrates a cross-sectional view of a structure comprising a spacer structure 210, in accordance with some embodiments. The structure shown in FIG. 14 is similar to the structure shown in FIG. 13, except that the structure shown in FIG. 14 comprises a conformal cooling cover 169. The conformal cooling cover 169 is similar to the cooling cover 168 described previously for FIG. 11, except that a portion of the bottom of the conformal cooling cover 169 protrudes downward to contact the sealant 167. The protruding bottom portion of the conformal cooling cover 169 may protrude a distance D1 that is in the range of about 100 μm to about 5 mm, though other distances are possible. In other words, a central portion of the conformal cooling cover 169 has a greater thickness than outer portions of the conformal cooling cover 169. In some cases, the outer portions may be considered “recessed portions.” In some embodiments, the shape of a conformal cooling cover 169 allows for the use of ring structures 166 that extend above the lid 140. For example, FIG. 14 illustrates a ring structure 166 with a top surface that is higher (e.g., farther from the substrate 201) than a top surface of the lid 140. The “T-shape” of the conformal cooling cover 169 allows for the use of taller ring structures 166 or taller spacer structures 210 without increasing the overall height of the structure. Similarly, the conformal cooling cover 169 allows for a smaller overall height of the structure when using thinner semiconductor devices 100 or lids 140. In this manner, the use of a conformal cooling cover 169 as described herein can allow for more flexible design and allow for smaller structures to be formed without sacrificing robustness.

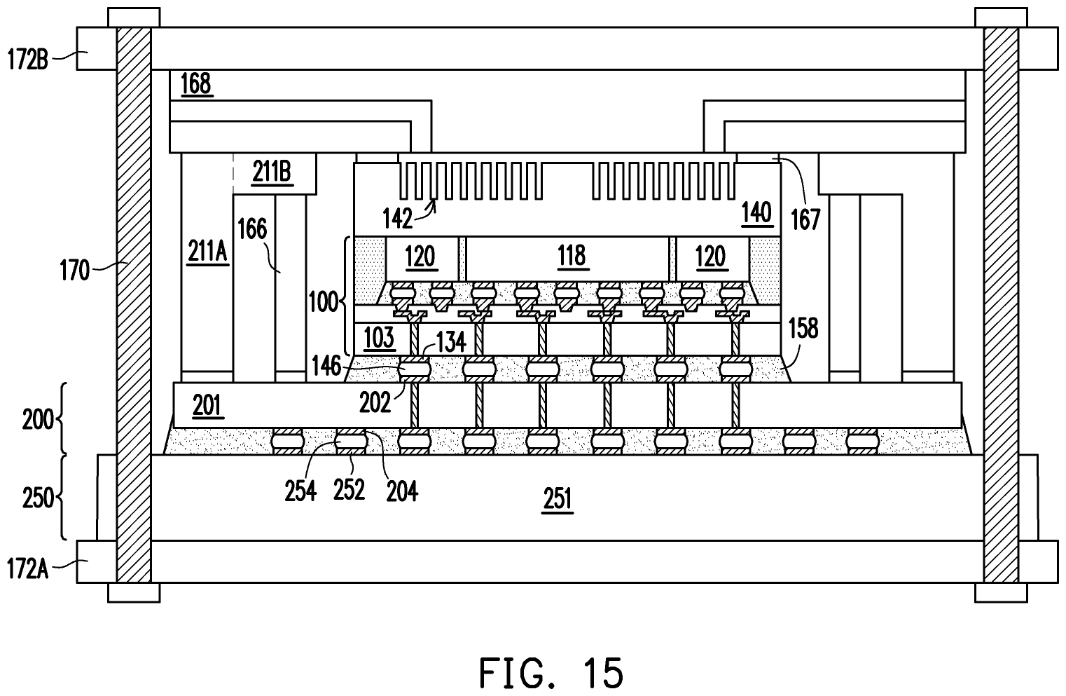

FIG. 15 illustrates a cross-sectional view of a structure comprising a L-shaped spacer structure 211, in accordance with some embodiments. The structure shown in FIG. 15 is similar to the structure shown in FIG. 13, except that the structure shown in FIG. 15 comprises a L-shaped spacer structure 211. The L-shaped spacer structure 211 is similar to the spacer structure 210 described previously, except that the L-shaped spacer structure 211 comprises a vertical portion 211A and a horizontal portion 211B that extends under the cooling cover 168 and extends over the ring structure 166. The vertical portion 211A and the horizontal portion 211B may be separate pieces that have been attached together, or may be regions of a single piece as shown in FIG. 15. The vertical portion 211A may be similar to the spacer structure 210. For example, the vertical portion 211A may extend between a top surface of the substrate 201 and a bottom surface of the cooling cover 168. The horizontal portion 211B protrudes laterally at the top of the vertical portion 211A, and the top surfaces of the vertical portion 211A and the horizontal portion 211B may be level. In some embodiments, the horizontal portion 211B may protrude laterally from the vertical portion 211A a lateral distance that is in the range of about 0.5 mm to about 10 mm. In some embodiments, the horizontal portion 211B may have a thickness that is in the range of about 300 μm um to about 3 mm. Other distances or thicknesses are possible.

As shown in FIG. 15, some or all of the top surface of the horizontal portion 211B may contact the bottom surface of the cooling cover 168. A bottom surface of the horizontal portion 211B may contact a top surface of the ring structure 166, in some embodiments. The horizontal portion 211B of the L-shaped spacer structure 211 can allow for improved distribution of forces due to the frame 172, in some cases. For example, the increased contact area of the horizontal portion 211B against the cooling cover 168 allows for the force of the cooling cover 168 pressing against the L-shaped spacer structure 211 to be more evenly distributed, which can reduce stress and strain. Additionally, for embodiments in which the horizontal portion 211B contacts the ring structure 166, the pressing force from the cooling cover 168 can also be distributed by the horizontal portion 211B into the ring structure 166. In other embodiments, an adhesive or the like may be between the ring structure 166 and the horizontal portion 211B. An L-shaped spacer structure 211 as described herein can provide improved support, less chance of breakage, and enhanced robustness.

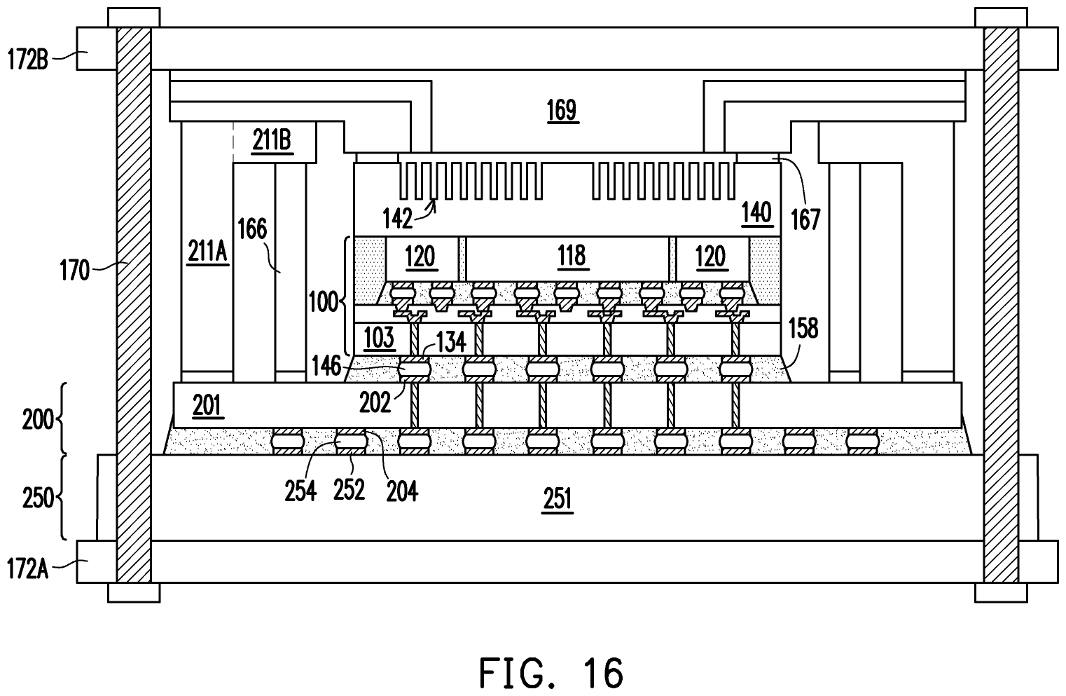

FIG. 16 illustrates a cross-sectional view of a structure comprising a L-shaped spacer structure 211 and a conformal cooling cover 169, in accordance with some embodiments. The structure shown in FIG. 16 is similar to the structure shown in FIG. 14, except that the structure shown in FIG. 16 comprises a L-shaped spacer structure 211, which may be similar to the L-shaped spacer 211 described for FIG. 15. In some cases, the use of a conformal cooling cover 169 allows for an L-shaped spacer structure 211 to be more easily incorporated into a structure, as the horizontal portion 211B of the L-shaped spacer structure 211 can contact the recessed portion of the conformal cooling cover 169. In this manner, an L-shaped spacer structure 211 may be used even for structures having relatively tall ring structures 166, for example.

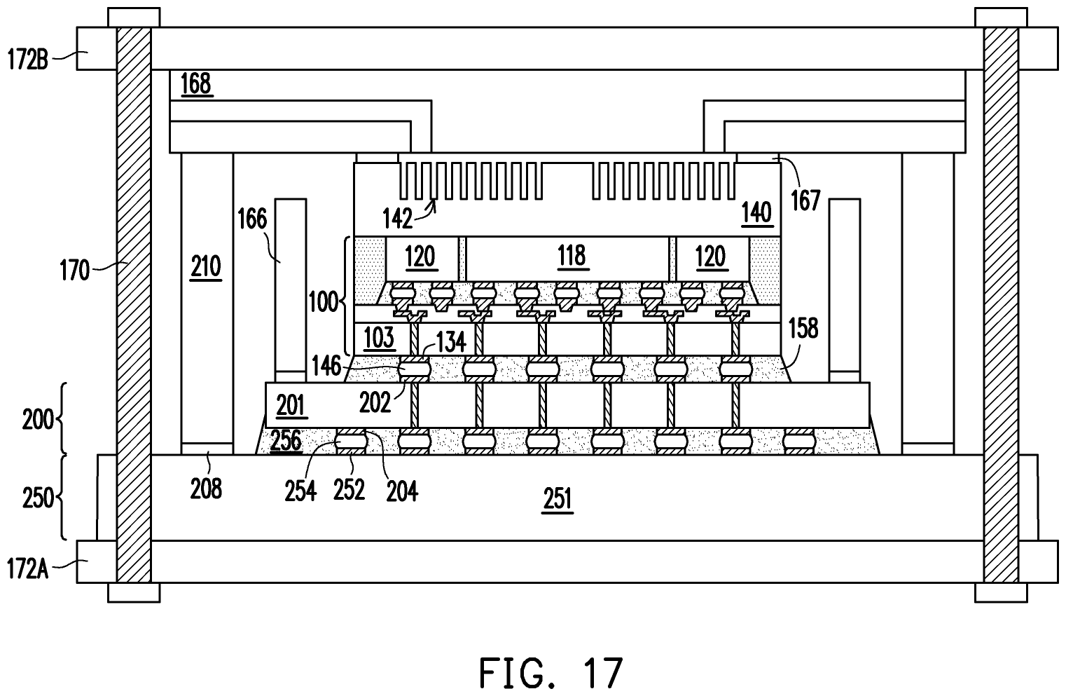

FIG. 17 illustrates a cross-sectional view of a structure comprising a spacer structure 210, in accordance with some embodiments. The structure shown in FIG. 17 is similar to the structure shown in FIG. 13, except that the spacer structure 210 is attached to the package substrate 250 instead of the device substrate 200. In other words, the spacer structure 210 extends from a top surface of the substrate 251 to a bottom surface of the cooling cover 168. The spacer structure 210 may be attached to the package substrate 250 using techniques similar to those described previously for FIG. 9. For example, an adhesive 208 may be deposited on the substrate 251, and then the spacer structure 210 may be placed on the adhesive 208. In other embodiments, the adhesive 208 is applied to the spacer structure 210. In some embodiments, a spacer structure 210 attached to a package substrate 250 may have a vertical thickness that is in the range of about 500 μm to about 5 mm, though other thicknesses are possible. In some cases, attaching the spacer structure 210 to the package substrate 250 may reduce the amount of pressing force distributed to the device substrate 200, and thus may reduce stress, warping, or risk of damage to the device substrate 200.

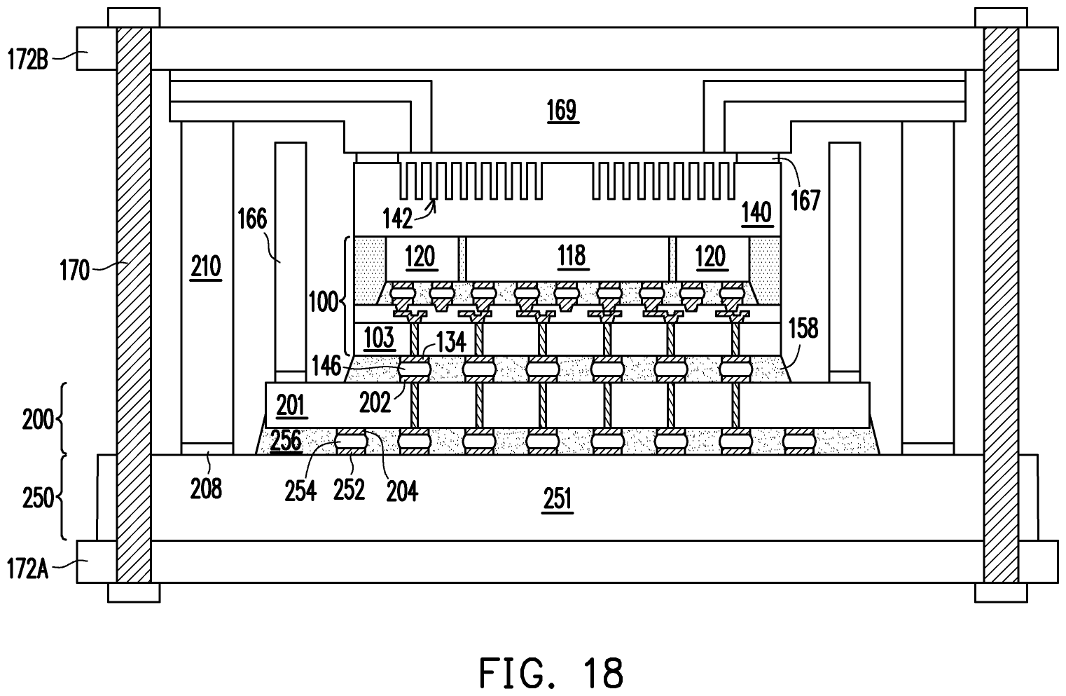

FIG. 18 illustrates a cross-sectional view of a structure comprising a conformal cooling cover 169, in accordance with some embodiments. The structure shown in FIG. 18 is similar to the structure shown in FIG. 14, except that the spacer structure 210 is attached to the package substrate 250 instead of the device substrate 200. The conformal cooling cover 169 may be similar to the conformal cooling cover 169 described previously for FIG. 14.

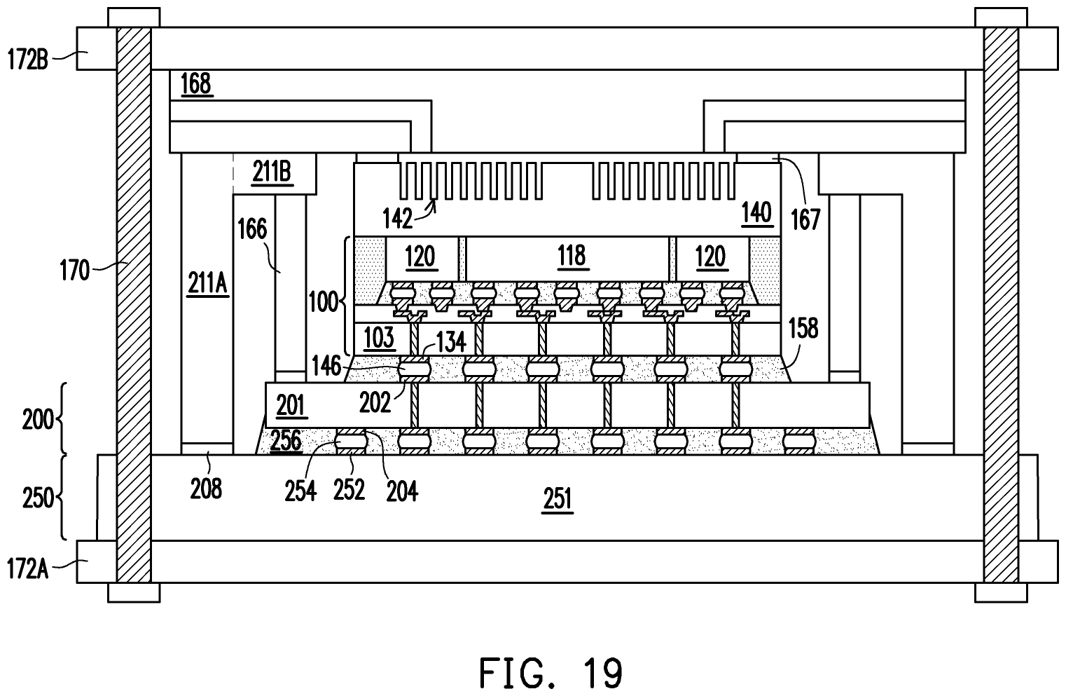

FIG. 19 illustrates a cross-sectional view of a structure comprising a L-shaped spacer structure 211, in accordance with some embodiments. The structure shown in FIG. 19 is similar to the structure shown in FIG. 15, except that the L-shaped spacer structure 211 is attached to the package substrate 250 instead of the device substrate 200. The L-shaped spacer structure 211 may be similar to the L-shaped spacer structure 211 described previously for FIG. 15.

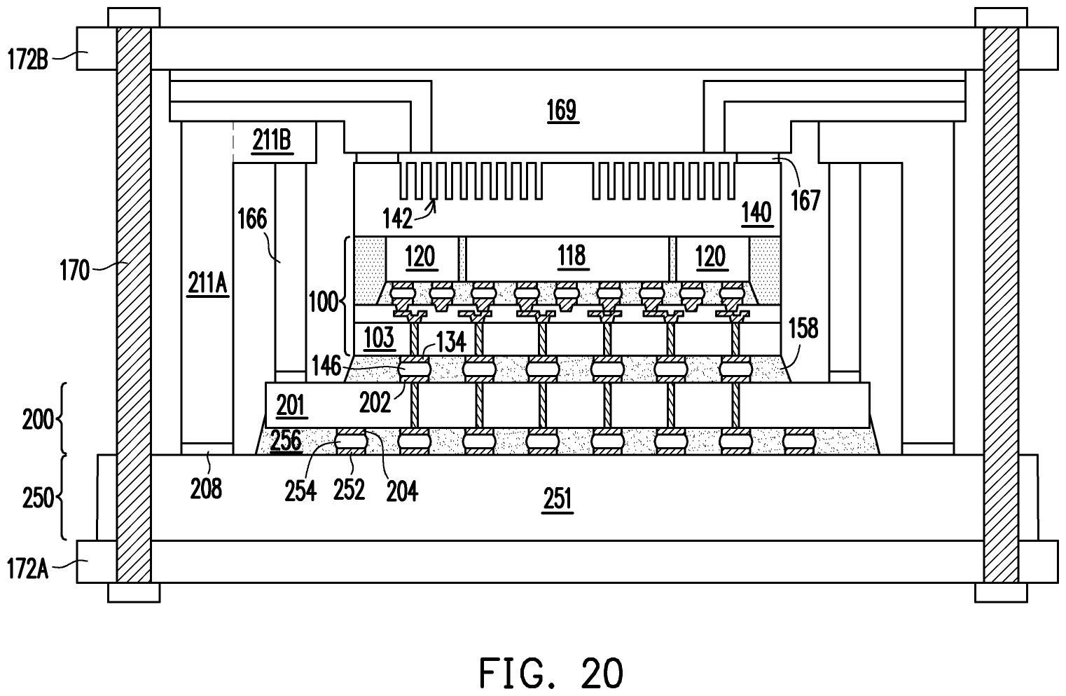

FIG. 20 illustrates a cross-sectional view of a structure comprising a L-shaped spacer structure 211 and a conformal cooling cover 169, in accordance with some embodiments. The structure shown in FIG. 20 is similar to the structure shown in FIG. 16, except that the L-shaped spacer structure 211 is attached to the package substrate 250 instead of the device substrate 200. In other words, the L-shaped spacer structure 211 extends from a top surface of the substrate 251 to a recessed portion of the conformal cooling cover 169. These are examples, and other structures comprising spacer structures 210, L-shaped spacer structures 211, cooling covers 168, and/or conformal cooling covers 169 are possible.

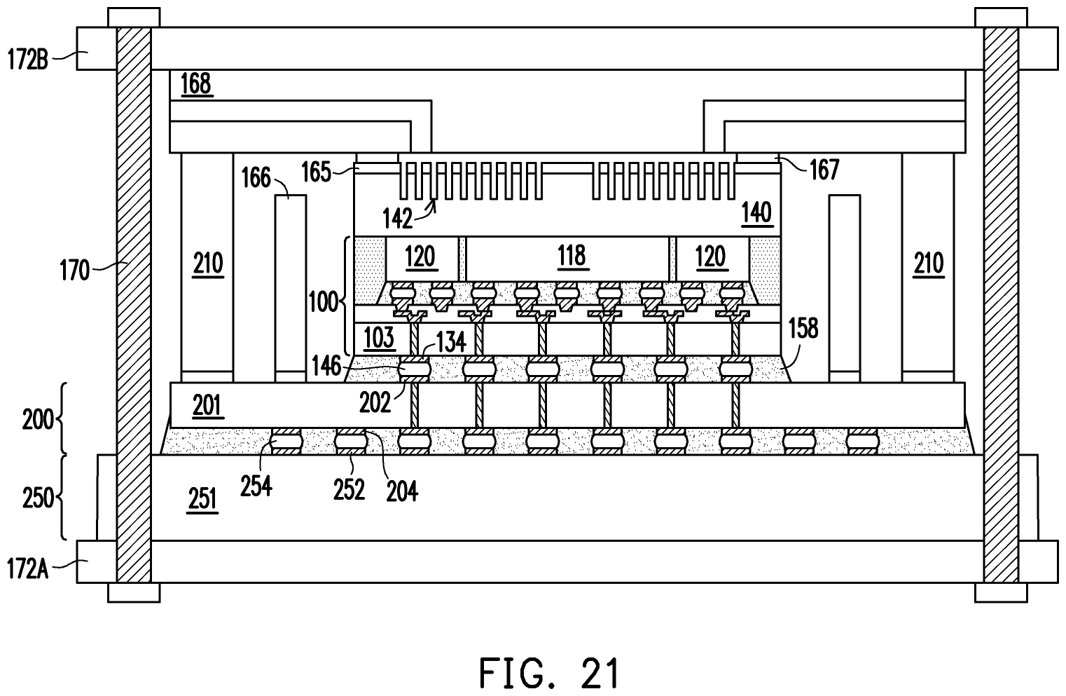

FIG. 21 illustrates a cross-sectional view of a structure comprising a spacer structure 210, in accordance with some embodiments. The structure shown in FIG. 18 is similar to the structure shown in FIG. 13, except that a cushion material 165 is formed on the lid 140. The sealant 167 may be deposited on the cushion material 165. The cushion material 165 may be a soft or pliable material that provides additional cushioning or protection for the lid 140. The cushion material 165 may be, for example, a polymer, a polyimide, a photoresist, or the like. The cushion material 165 may be formed using any suitable technique, such as spin-on, lamination, printing, or the like. Other materials or techniques are possible. The cushion material 165 may be formed having a thickness in the range of about 0.1 μm to about 1 mm, though other thicknesses are possible. The cushion material 165 may be included in other embodiments, including any of the various embodiments described herein.

Embodiments described herein may achieve advantages. The use of a spacer structure as described herein can keep a cooling system component from contacting a semiconductor device or an overlying thermal structure (e.g., a lid). In this manner, a spacer structure can reduce the risk of damaging a semiconductor device when the cooling system component is attached to the semiconductor device. The spacer structure can distribute stress or strain forces within a structure more evenly, and reduce the stress or strain forces that a semiconductor device within the structure experiences. This can reduce warping or cracking of the semiconductor device. A spacer structure can also improve the robustness of a structure or package. A spacer structure can be used in various configurations, such as at the device substrate level or at a package substrate level. The spacer structure described herein may be used for a variety of packages or semiconductor structures, such as flip-chip, integrated fan-out (InFO), chip-on-wafer-on-substrate (CoWoS), system-on-integrated-chip (SoIC), or the like. A spacer structure may be formed having an L-shape, which can provide improved robustness and reduced chance of damage. A cooling system component may be formed having recessed portions to accommodate the shape of an L-shaped spacer structure.

In accordance with some embodiments of the present disclosure, a device includes an integrated circuit die attached to a substrate; a lid attached to the integrated circuit die; a sealant on the lid; a spacer structure attached to the substrate adjacent the integrated circuit die; and a cooling cover attached to the spacer structure, wherein the cooling cover extends over the lid, wherein the cooling cover attached to the lid by the sealant. In an embodiment, the device includes a ring structure on the substrate, wherein the ring structure is between the spacer structure and the integrated circuit die. In an embodiment, the cooling cover extends over the ring structure. In an embodiment, a top surface of the ring structure is lower than a top surface of the lid. In an embodiment, the lid includes a plurality of channels. In an embodiment, the cooling cover is configured to provide coolant to a gap between the cooling cover and the lid. In an embodiment, the spacer structure includes a vertical portion and a horizontal portion, wherein a top surface of the horizontal portion contacts the cooling cover. In an embodiment, a portion of the cooling cover that extends over the lid has a thickness greater than a portion of the cooling cover that is attached to the spacer structure. In an embodiment, the device includes a frame that presses the cooling cover against the spacer structure.

In accordance with some embodiments of the present disclosure, a device includes a first substrate; a second substrate connected to the first substrate; a spacer structure attached to the first substrate, wherein the spacer structure encircles the first substrate; a semiconductor device connected to the second substrate; a ring structure attached to the second substrate, wherein the ring structure encircles the semiconductor device; and a cooling cover attached to the spacer structure, wherein the cooling cover is vertically separated from the ring structure and the semiconductor device. In an embodiment, a top surface of the ring structure is lower than a top surface of the spacer structure. In an embodiment, a portion of the spacer structure extends between a bottom surface of the cooling cover and a top surface of the ring structure. In an embodiment, the device includes a lid attached to the semiconductor device, wherein the cooling cover is attached to the lid. In an embodiment, the cooling cover is attached to the lid by a sealant around a perimeter of the lid. In an embodiment, the cooling cover is configured to be coupled to a heat transfer unit, wherein the heat transfer unit is configured to supply liquid coolant to the cooling cover. In an embodiment, the bottom of the cooling cover is level.

In accordance with some embodiments of the present disclosure, a method includes attaching a lid to a semiconductor device, wherein the lid includes coolant channels; attaching the semiconductor device to a substrate; attaching a ring structure to the substrate adjacent the semiconductor device; attaching a spacer on the substrate adjacent the ring structure, wherein the spacer extends higher than the ring structure; and attaching a cover to the spacer and the lid. In an embodiment, attaching the spacer includes depositing an adhesive on the substrate. In an embodiment, the spacer physically contacts a top surface of the ring structure. In an embodiment, the method includes flowing a liquid coolant between the lid and the cover.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
an integrated circuit die attached to a substrate;
a lid attached to the integrated circuit die;
a sealant on the lid;
a spacer structure attached to the substrate adjacent the integrated circuit die; and
a cooling cover attached to the spacer structure, wherein the cooling cover extends over the lid, wherein the cooling cover attached to the lid by the sealant.

2. The device of claim 1 further comprising a ring structure on the substrate, wherein the ring structure is between the spacer structure and the integrated circuit die.

3. The device of claim 2, wherein the cooling cover extends over the ring structure.

4. The device of claim 2, wherein a top surface of the ring structure is lower than a top surface of the lid.

5. The device of claim 1, wherein the lid comprises channels.

6. The device of claim 1, wherein the cooling cover is configured to provide coolant to a gap between the cooling cover and the lid.

7. The device of claim 1, wherein the spacer structure comprises a vertical portion and a horizontal portion, wherein a top surface of the horizontal portion contacts the cooling cover.

8. The device of claim 1, wherein a portion of the cooling cover that extends over the lid has a thickness greater than a portion of the cooling cover that is attached to the spacer structure.

9. The device of claim 1 further comprising a frame that presses the cooling cover against the spacer structure.

10. A device comprising:
a first substrate;
a second substrate connected to the first substrate;
a spacer structure attached to the first substrate, wherein the spacer structure encircles the first substrate;
a semiconductor device connected to the second substrate;
a ring structure attached to the second substrate, wherein the ring structure encircles the semiconductor device; and
a cooling cover attached to the spacer structure, wherein the cooling cover is vertically separated from the ring structure and the semiconductor device.

11. The device of claim 10, wherein a top surface of the ring structure is lower than a top surface of the spacer structure.

12. The device of claim 10, wherein a portion of the spacer structure extends between a bottom surface of the cooling cover and a top surface of the ring structure.

13. The device of claim 10, further comprising a lid attached to the semiconductor device, wherein the cooling cover is attached to the lid.

14. The device of claim 13, wherein the cooling cover is attached to the lid by a sealant around a perimeter of the lid.

15. The device of claim 10, wherein the cooling cover is configured to be coupled to a heat transfer unit, wherein the heat transfer unit is configured to supply liquid coolant to the cooling cover.

16. The device of claim 10, wherein the bottom of the cooling cover is level.

17. A method comprising:
attaching a lid to a semiconductor device, wherein the lid comprises coolant channels;
attaching the semiconductor device to a substrate;
attaching a ring structure to the substrate adjacent the semiconductor device;
attaching a spacer on the substrate adjacent the ring structure, wherein the spacer extends higher than the ring structure; and
attaching a cover to the spacer and the lid.

18. The method of claim 17, wherein attaching the spacer comprises depositing an adhesive on the substrate.

19. The method of claim 17, wherein the spacer physically contacts a top surface of the ring structure.

20. The method of claim 17 further comprising flowing a liquid coolant between the lid and the cover.
